(19) United States
(12) Patent Application Publication
(10) Pub. No.: US 2024/0389273 A1
(43) Pub. Date: Nov. 21, 2024

(54) HEAT DISSIPATION APPARATUS

(71) Applicant: BITMAIN TECHNOLOGIES INC., Beijing (CN)

(72) Inventors: Zesen NIE, Beijing (CN); Mingliang HAO, Beijing (CN); Zhihao ZHU, Beijing (CN); Yinchuang YANG, Beijing (CN)

(21) Appl. No.: 18/761,035

(22) Filed: Jul. 1, 2024

(30) Foreign Application Priority Data
May 15, 2023 (CN) 202321157022.X

(51) Int. Cl. H05K 7/20

(52) U.S. Cl. CPC H05K 7/20427

(57) ABSTRACT

A heat dissipation apparatus, includes: a heat spreading structure and a first surface heat dissipation structure; where the heat spreading structure at least includes a first surface and a second surface which are oppositely arranged, the first surface is connected with a package of a chip to be heat dissipated; and the first surface heat dissipation structure is formed on the second surface by a copper powder spraying process. In the present disclosure, by the copper powder spraying process, the first surface heat dissipation structure formed has a higher adhesion strength, and a morphology of the first surface heat dissipation structure can be adjusted, thereby increasing the number of vaporization core and enhancing the boiling heat exchange effect of the heat dissipation apparatus.

### CROSS-REFERENCE TO RELATED APPLICATION

This application claims priority to Chinese Patent Application No. 202321157022.X, filed on May 15, 2023, which is incorporated by reference in its entirety.

### TECHNICAL FIELD

The present disclosure relates to, but is not limited to, the field of electronic devices, and in particular to a heat dissipation apparatus.

### BACKGROUND

Phase change liquid cooling is to use a phase change coolant as a heat transfer medium, and in a heat transfer process, the coolant absorbs and releases heat and undergoes a phase change, which is usually accompanied by a small amount of supercooling or overheating, but mainly relies on the latent heat of phase change of the substance to transfer heat. Where immersion phase change liquid cooling technology is using a liquid phase change to take away the heat directly from a heating generating device, reducing the thermal resistance of heat transfer engineering, and compared with cold plate liquid cooling, it has higher heat transfer efficiency and is the most energy-saving and efficient refrigeration mode in liquid cooling.

At present, the boiling enhancement design applied in the immersion phase change liquid cooling technology has relative disadvantages in enhancement degree, processing difficulty and controllability, which is specifically manifested in that: this technology only uses a micro-rib structure to increase a contact area with a phase change working medium, thereby increasing the number of vaporization core. This technology requires to make a very fine micro-structure, which increases processing difficulty and production cost, and moreover, it is limited in the level of mechanical processing. Thus, it does not have high controllable performance in specific implementations, and cannot meet the requirement in diameter of vaporization core under different system pressures.

### SUMMARY

This disclosure provides a heat dissipation apparatus, which can increase the number of vaporization core and enhance a boiling heat exchange effect.

One aspect of the present disclosure provides a heat dissipation apparatus, the heat dissipation apparatus includes a heat spreading structure and a first surface heat dissipation structure; where, the heat spreading structure at least includes a first surface and a second surface which are oppositely arranged, the first surface is connected with a package of a chip to be heat dissipated; and the first surface heat dissipation structure is formed on the second surface by using a copper powder spraying process.

In some possible embodiments, the heat spreading structure further includes a third surface, and the heat dissipation apparatus further includes a second surface heat dissipation structure, where the third surface is connected with the first surface and the second surface; the second surface heat dissipation structure is formed on the third surface by using a copper powder spraying process.

In some possible embodiments, a spraying thickness used in the copper powder spraying process is 0.05-0.15 mm.

In some possible embodiments, a spraying pressure used in the copper powder spraying process is 0.2-1 MPa.

In some possible embodiments, the heat spreading structure further includes at least one heat spreading block, and the at least one heat spreading block is provided above the package of the chip to be heat dissipated; a bottom surface of the at least one heat spreading block constitutes the first surface, and a top surface of the at least one heat spreading block constitutes the second surface.

In some possible embodiments, the first surface is connected with the package of the chip to be heat dissipated.

In some possible embodiments, a shape of the heat spreading block is one of the following: cuboid, cube, frustum and cylinder.

In some possible embodiments, the package of the chip to be heat dissipated is welded to the first surface.

In some possible embodiments, a heat conducting medium layer is filled between the package of the chip to be heat dissipated and the first surface.

In some possible embodiments, the first surface heat dissipation structure is formed on the second surface.

In some possible embodiments, a surface of the first surface heat dissipation structure has a rough pattern.

In the present disclosure, the first surface heat dissipation structure is formed on the second surface of the heat spreading structure by a copper powder spraying process, so that the first surface heat dissipation structure has higher adhesion strength, and the copper powder spraying process can adjust a morphology of the first surface heat dissipation structure by adjusting particle diameter of copper powder and spraying pressure, and increase the number of vaporization core and enhance the boiling heat exchange effect of the heat dissipation apparatus by increasing a surface area of the first surface heat dissipation structure.

It should be understood that the foregoing general description and the following detailed description are exemplary and explanatory only and do not limit the present disclosure.

### BRIEF DESCRIPTION OF DRAWINGS

The accompanying drawings here, which are incorporated into the specification and form a part of the specification, illustrate embodiments in accordance with the present disclosure and used together with the specification to explain the principle of the present disclosure.

FIG. 1 is a schematic diagram of a first structure of a heat dissipation apparatus in an embodiment of the present disclosure.

FIG. 2 is a schematic diagram of a second structure of a heat dissipation apparatus in an embodiment of the present disclosure.

FIG. 3 is a schematic diagram of a third structure of a heat dissipation apparatus in an embodiment of the present disclosure.

FIG. 4 is a schematic diagram of a structure of a heat spreading structure in an embodiment of the present disclosure.

FIG. 5 is a schematic diagram of another structure of a heat spreading structure in an embodiment of the present disclosure.

FIG. 6 is a process flow diagram of a heat dissipation apparatus in an embodiment of the present disclosure.

### DESCRIPTION OF REFERENCE SIGNS IN THE ACCOMPANYING DRAWINGS

10—heat dissipation apparatus; 11—heat spreading structure; 11A—first surface; 11B—second surface; 11C—third surface; 111—heat spreading block; 12—first surface heat dissipation structure; 13—second surface heat dissipation structure.

### Description of Embodiments

A detailed explanation of exemplary embodiments will be made here, the examples are illustrated in the accompanying drawings. When the following description relates to the accompanying drawings, the same numbers in different accompanying drawings indicate the same or similar elements unless otherwise indicated. The implementations described in the following exemplary embodiments do not represent all implementations consistent with the present disclosure. On the contrary, they are merely examples of apparatuses consistent with some aspects of the present disclosure as detailed in the appended claims.

The skilled in the art will easily think of other embodiments of the present disclosure after considering the specification and practicing the present disclosure disclosed herein. The present disclosure is intended to cover any variations, uses or adaptations of the present disclosure, these variations, uses or adaptations follow the general principle of the present disclosure and include common knowledge or conventional technical means in the art that are not disclosed in the present disclosure. The specification and examples are only considered exemplary, and the true scope and spirit of the present disclosure are indicated by the claims.

In order to explain the technical solutions described in the present disclosure, the following description will be made through specific examples.

Immersion liquid cooling technology is to perform heat exchange by immersing a headed component to bring the headed component into direct contact with a liquid. According to whether there is a phase change in the medium, the immersion liquid cooling technology can be divided into immersion single-phase liquid cooling and immersion phase change liquid cooling. Where, in the immersion single-phase liquid cooling, a dielectric coolant remains in a liquid state, an electronic component is directly immersed in the dielectric coolant, the dielectric coolant is placed in a sealed but easily accessible container, and heat is transferred from the electronic component to the dielectric coolant, a circulating pump is usually used to flow the heated coolant to a heat exchanger, the heated coolant is cooled in the heat exchanger and circulated back to the container, where the coolant always remains in liquid state in the process of circulating heat dissipation, and does not undergo a phase change, and after the heat is taken away by the low-temperature coolant, the temperature of the low-temperature coolant rises, and the temperature-raised coolant flows to other area and then is recooled to complete a cycle. The immersion phase change liquid cooling is using a phase change coolant as heat transfer medium, and in a process of heat transfer, the coolant absorbs and releases heat and undergoes a phase change, which is usually accompanied by a small amount of supercooling or overheating, but mainly relies on the latent heat of phase change of substance to transfer heat. In an immersion liquid phase change cooling system, high heat-generating components such as server motherboard, central processing unit (CPU) and memory are completely immersed in the coolant; in a working state, the heat-generating components will generate heat, causing the coolant to warm up, and when a temperature of the coolant rises to a boiling point corresponding to the system pressure, the coolant undergoes a phase change, changing from liquid to gas, and absorbs heat through vaporization heat to realize heat transfer. The immersion phase change liquid cooling technology uses liquid phase change to directly take away heat, reducing the thermal resistance of heat transfer engineering, and compared with a cold plate liquid cooling, it has higher heat transfer efficiency and is the most energy-saving and efficient refrigeration mode in liquid cooling.

At present, the boiling enhancement design applied in the immersion phase change liquid cooling technology has relative disadvantages in terms of enhancement degree, processing difficulty, and controllable performance. Patent CN112151481A discloses a surface enhanced boiling heat dissipation structure, which uses a micro-rib structure to increase a contact area with a phase change working medium, thereby increasing the number of vaporization core. This technology requires to make a very fine micro-structure, which increases processing difficulty and production cost, and moreover, it is limited in level of mechanical processing. Thus, it does not have high controllable performance in specific implementations, and cannot meet the diameter requirement of vaporization core under different system pressures.

To address the preceding problem, an embodiment of the present disclosure provides a heat dissipation apparatus, which can increase the number of vaporization core and enhance a boiling heat exchange effect.

It should be noted that the heat dissipation apparatus in the embodiment of the present disclosure achieves heat dissipation of a chip to be heat dissipated through an immersion phase change liquid cooling technology. The heat dissipation apparatus in the following embodiments can be immersed in a phase change working medium during use.

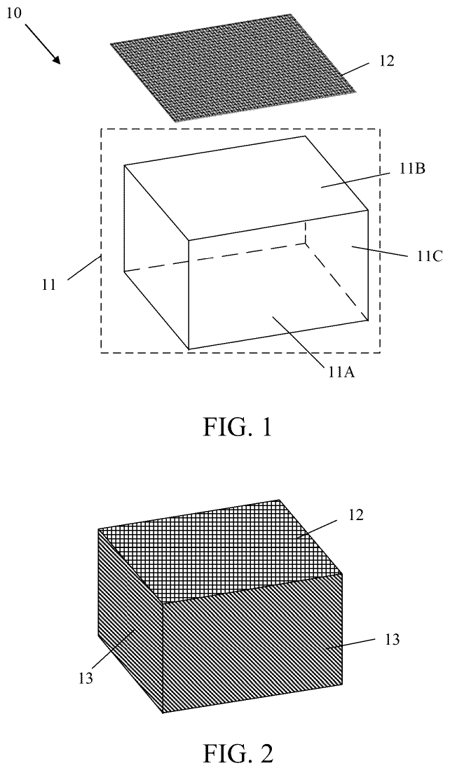

FIG. 1 is a schematic diagram of a first structure of a heat dissipation apparatus in an embodiment of the present disclosure. As shown in FIG. 1, a heat dissipation apparatus 10 includes: a heat spreading structure 11 and a first surface heat dissipation structure 12, where the heat spreading structure 11 at least includes a first surface 11A and a second surface 11B which are oppositely arranged, the first surface 11A is connected with a package of a chip to be heat dissipated; the first surface heat dissipation structure 12 is adhered to the second surface 11B, the first surface heat dissipation structure 12 is formed on the second surface 11B by using a copper powder spraying process. The heat spreading structure 11 further includes a third surface 11C, and the third surface 11C is connected with the first surface 11A and the second surface 11B.

In an example, the heat dissipation apparatus 10 is used for heat exchange with the chip to be heat dissipated to achieve heat dissipation. At this time, the heat spreading structure 11 in the heat dissipation apparatus 10 is directly in contact and fixedly connected to a package of the chip to be heat dissipated.

In an embodiment, as shown in FIG. 1, a surface of the heat spreading structure 11 in direct contact with the chip to be heat dissipated is the first surface 11A, and a surface of the heat spreading structure 11 parallel to the first surface 11A is the second surface 11B. The heat generated by the chip to be heat dissipated during operation process is transferred to the first surface 11A of the heat spreading structure 11, and then further transferred from the first surface 11A to the second surface 11B, and finally, the first surface heat dissipation structure 12 provided on the second surface 11B exchanges heat with a phase change working medium, causing boiling of the phase change working medium.

In an embodiment, in order to process different surface morphologies, the first surface heat dissipation structure 12 may be formed by treating the second surface 11B using a special surface treatment process (i.e., copper powder spraying process).

In some possible embodiments, FIG. 2 is a schematic diagram of a second structure of the heat dissipation apparatus in an embodiment of the present disclosure. As shown in FIG. 2, the heat dissipation apparatus 10 further includes a second surface heat dissipation structure 13, which is formed on the third surface 11C by using a copper powder spraying process.

In an embodiment, the heat dissipation apparatus 10 is placed in a phase change working medium, and the heat spreading structure 11 is provided as a cuboid (it may also be in other forms, and this embodiment takes the cuboid as an example but is not limited to thereto), a bottom surface of the heat spreading structure 11 (i.e., the first surface 11A) is in contact with the package of the chip to be heat dissipated, a top surface of the heat spreading structure 11 is a second surface 11B, and other four surfaces except for the first surface 11A and the second surface 11B are the third surface 11C of the heat spreading structure 11. Both the second surface 11B and the third surface 11C are treated by using a copper powder spraying process, forming the first surface heat dissipation structure 12 and the second surface heat dissipation structure 13. The first surface heat dissipation structure 12 and the second surface heat dissipation structure 13 can transfer the heat generated by the chip to be heat dissipated to the phase change working medium, causing boiling of the phase change working medium.

In the embodiment of the present disclosure, the second surface 11B and the third surface 11C of the heat spreading structure 11 are both heat dissipation surfaces. Existence of multiple heat dissipation surfaces at the same time can effectively reduce the superheat degree of wall surface of the heat spreading structure 11 and further reduce a temperature of the chip to be heat dissipated.

In some possible embodiments, a spraying pressure used in implementation of the copper powder spraying process used on the preceding second surface 11B and/or the third surface 11C is 0.2-1 MPa.

In some possible embodiments, a spraying thickness used in implementation of the copper powder spraying process used on the preceding second surface 11B and/or the third surface 11C is 0.05-0.15 mm.

In the embodiments of the present disclosure, in order to verify the heat spreading effect of the second surface 11B and/or the third surface 11C when the copper powder spraying process employs a spraying pressure of 0.2-1 MPa and a spraying thickness of 0.05-0.15 mm, experimental data in Table 1 is illustrated.

TABLE 1

| | Pressure | | | | |
|---|---|---|---|---|---|
| Thickness | 0.2 MPa | 0.4 MPa | 0.6 MPa | 0.8 MPa | 1 MPa |
| 0.05 mm | 21 | 19 | 17 | 16 | 15 |
| 0.1 mm | 25 | 23 | 22 | 19 | 18 |
| 0.15 mm | 29 | 27 | 25 | 24 | 22 |

As shown in Table 1, the above values are temperature differences between the temperature of the chip to be heat dissipated and a saturation temperature of the phase change working medium. The smaller the temperature difference, the better the heat dissipation effect. It can be seen that, the heat dissipation effect of the heat dissipation apparatus is the best when the spraying pressure is 1 MPa and the spraying thickness is 0.05 mm, which is the optimal choice. However, when other spraying pressures and thicknesses within ranges of 0.2-1 MPa and 0.05-0.15 mm are used, the heat dissipation apparatus still maintains a good heat dissipation effect.

In the embodiments of the present disclosure, in order to verify the adhesion strength of the first surface heat dissipation structure 12 formed by the copper powder spraying process on the second surface 11B, an adhesion of coating can be tested using, for example, a cross-cut test. Where, a control group of this experiment is a copper mesh welded layer formed by copper mesh welding and the copper mesh sintered layer formed by copper mesh sintering. An operation method for testing the adhesion of coating by using the cross-cut test is as follows.
(1) First, 11 parallel and equally spaced cut marks are cut out on the first surface heat dissipation structure 12, the copper mesh welded layer, and the copper mesh sintered layer, and then cut marks with the same number and spacing as the former are vertically cut out, where a cutter with a spacing of 2 mm between cross cutting blades is chosen.
(2) When using manual cutting, the force should be uniform and the speed should be stable without trembling, so that the blade can just penetrate the coating and touch its bottom during cutting.
(3) After cutting, 100 squares will appear on the test boards. Using a soft bristle brush to gently brush off chips along two diagonal directions of the squares, and then checking and evaluating the adhesion of coating.

Evaluation standard for the adhesion of coating tested using the above cross-cut test (GB/T9286-88) are shown in Table 2.

TABLE 2

| Classification | Description |
|---|---|
| 0 | Cut edge is completely flat, none of squares falls off |
| 1 | A few flakes separated are separated from the coating at |
| | intersection of cut edges, but an influence on cross |
| | cut area is obviously not more than 5% |
| 2 | Coating that falls off at edge or intersection of cut |
| | edges is obviously more than 5%, but the influence |
| | is obviously not more than 15% |
| 3 | Coating along cut edge is partially or completely fallen |
| | off in large piece or different parts of square are |
| | partially or completely fallen off, which is obviously |
| | more than 15%, but the influence is obviously not |
| | more than 35% |
| 4 | Coating along cut edge is fallen off in large piece |
| | or some squares are partially or completely fallen off, |
| | which is obviously more than 35%, but the influence |
| | is obviously not more than 65% |
| 5 | Severe falling off of more than Level 4 |

In the foregoing embodiments, by observing the surface morphology of the first surface heat dissipation structure 12, the copper mesh welded layer, and the copper mesh sintered layer after the cross-cut test, it can be found that the classification of the first surface heat dissipation structure 12 is significantly lower than those of the copper mesh welded layer and the copper mesh sintered layer. That is, treatment of the second surface 11B and the third surface 11C of the heat spreading structure 11 using the copper powder spraying process will result in a higher adhesion strength of copper powder on the heat spreading structure compared with use of the two technical means of copper mesh welding and copper mesh sintering. In addition, the copper powder spraying process can not only adjust the spraying thickness and spraying pressure, but also form surface morphology with different roughness by adjusting particle diameter of the copper powder, and thus it has better controllability and plasticity.

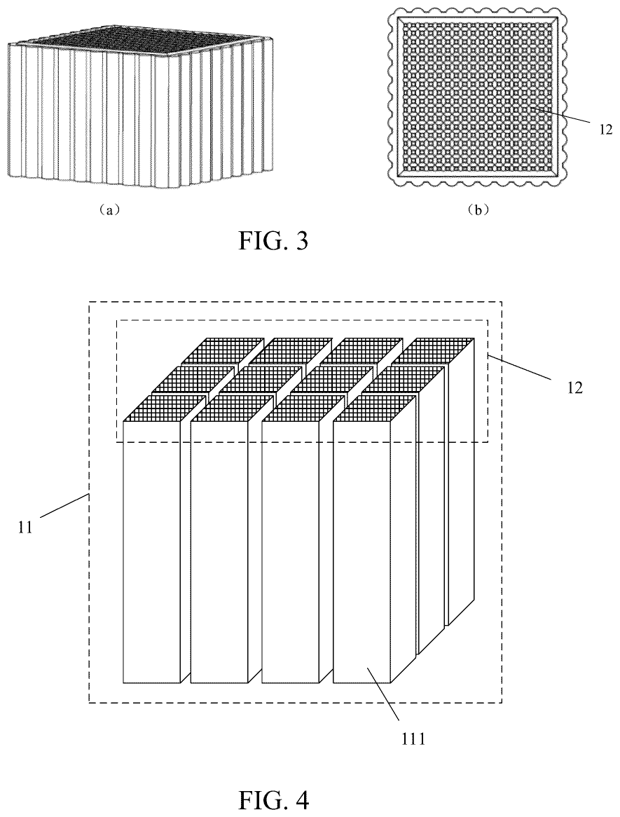

In some possible embodiments, FIG. 3 is a schematic diagram of a third structure of a heat dissipation apparatus in an embodiment of the present disclosure, where, (a) in FIG. 3 is a stereogram of the heat dissipation apparatus, and (b) in FIG. 3 is a top view of the heat dissipation apparatus. As shown in (a) and (b) in FIG. 3, the surface of the first surface heat dissipation structure 12 has a rough pattern.

It can be understood that the first surface heat dissipation structure 12 has a rough surface morphology due to processing by the copper powder spraying process. In this way, the vaporization core can be enhanced and the boiling heat exchange effect of the heat dissipation apparatus 10 in the phase change working medium can thus be enhanced.

In some possible embodiments, FIG. 4 is a schematic diagram of a structure of a heat spreading structure in an embodiment of the present disclosure. As shown in FIG. 4, the heat spreading structure 11 may further includes at least one heat spreading block 111, which is located on the package of the chip to be heat dissipated. A bottom surface of the at least one heat spreading block 111 forms the first surface 11A, and a top surface of the at least one heat spreading block 111 forms the second surface 11B. The first surface heat dissipation structure 12 can be obtained by treating the top surface of the at least one heat spreading block 111 using the copper powder spraying process.

It can be understood that the heat spreading structure 11 may have one or more heat spreading blocks 111. When the heat spreading structure 11 includes only one heat spreading block 111, length and width of the heat spreading block 111 are usually set to be greater than or equal to length and width of the chip to be heat dissipated. In this way, a heated surface of the chip to be heat dissipated can be fully covered, achieving high efficient heat exchange. When the heat spreading structure 11 includes multiple heat spreading blocks 111, the multiple heat spreading blocks 111 can be separately distributed on the surface of the chip to be heat dissipated according to an actual heat dissipation requirement, where the length and width of each heat spreading block 111 are smaller than the length and width of the chip to be heat dissipated. In this way, the multiple heat spreading blocks 111 can be separately distributed in local heating areas (such as areas where transistors are concentrated) of the chip to be heat dissipated for dissipating heat, which may save use cost of material while ensuring heat dissipation efficiency. It should be noted that when the heat spreading structure 11 includes only one heat spreading block 111, a surface of the heat spreading block 111 in direct contact with the package of the chip to be heat dissipated (i.e., the bottom surface of the heat spreading block 111) is the first surface 11A, and a surface thereof opposite to the first surface 11A is the second surface; when the heat spreading structure 11 includes multiple heat spreading blocks 111, surfaces of the multiple heat spreading blocks 111 in direct contact with the package of the chip to be dissipated (i.e., the bottom surfaces of the heat spreading blocks 111) together form the first surface 11A, and the top surfaces of the multiple heat spreading blocks 111 together form the second surface 11B.

In some possible embodiments, a shape of the heat spreading block 111 can be one of the following: cuboid, cube, frustum and cylinder. Of course, the heat spreading block 111 can also have other shapes, and this is not specifically limited in the embodiments of the present disclosure.

In the embodiments of the present disclosure, the heat spreading block 111 can be formed by a metal with high thermal conductivity, such as copper or aluminum, and a specific metal material can be selected according to an actual requirement, and is not specifically limited in the embodiments of the present disclosure.

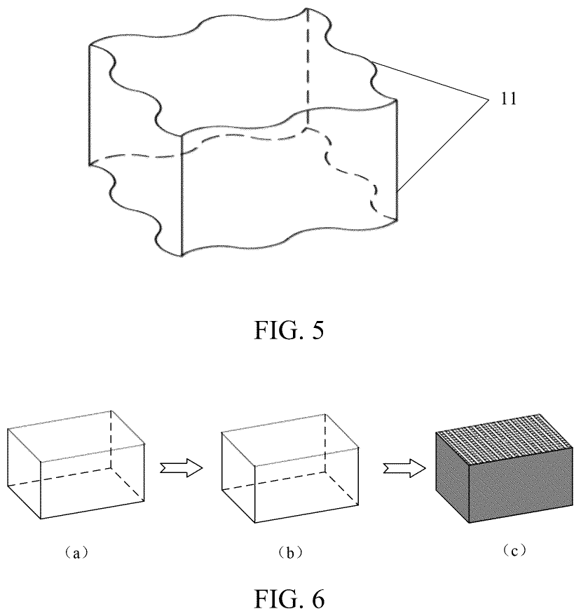

In some possible embodiments, FIG. 5 is a schematic diagram of another structure of a heat spreading structure in an embodiment of the present disclosure. As shown in FIG. 5, the second surface of the heat spreading structure 11 can be provided in a wavy shape.

It can be understood that when the second surface of the heat spreading structure 11 is provided in a wavy shape, a surface area of the heat spreading structure 11 can be increased, and the increased surface area may further enhance the boiling heat exchange effect. Similarly, the third surface 11C of the heat spreading structure 11 can also be provided in a wavy shape. It should be noted that when the second surface 11B of the heat spreading structure 11 is provided in a wavy shape, the first surface heat dissipation structure 12 is also correspondingly sprayed in a wavy shape, and when the third surface 11C of the heat spreading structure 11 is provided in a wavy shape, the second surface heat dissipation structure 13 is also correspondingly sprayed in a wavy shape. The second surface 11B and/or the third surface 11C of the heat spreading structure 11 is provided in a wavy shape, which is only one example, and they can also be set in other shapes as long as the heat spreading area of the heat spreading structure can be increased, and this is not specifically limited in the embodiments of the present disclosure.

In some possible embodiments, the first surface 11A is connected to the package of the chip to be dissipated.

It can be understood that the heat spreading structure 11 is a metal material and forms an oxide layer on the surface during forging process, and if the oxide skin is not removed timely during subsequent processing and use, the surface of the metal material is prone to folding, cracks, pits and other phenomena, which reduces the service life of the metal material. Therefore, in the embodiments of the present disclosure, before the heat spreading structure 11 is adhered to the chip to be heat dissipated, the first surface 11A of the heat spreading structure 11 can be treated by an oxide skin removal process, and the first surface 11A treated by the oxide skin removal process is connected to the package of the chip to be heat dissipated.

In some possible embodiments, the package of the chip to be heat dissipated is welded to the first surface 11A.

It can be understood that the first surface 11A treated by the oxide skin removal process can be connected to the package of the chip to be heat dissipated by welding.

In some possible embodiments, a heat conducting medium layer is filled between the package of the chip to be heat dissipated and the first surface 11A treated by the oxide skin removal process.

It can be understood that the heat conducting medium can be filled between the package of the chip to be heat dissipated and the first surface 11A of the heat spreading structure 11 after being treated by the oxide skin removal process, so as to enhance the heat exchange efficiency between the heat spreading structure 11 and the package of the chip to be heat dissipated, and after filling, the first surface 11A of the heat spreading structure 11 and the package of the chip to be heat dissipated are mechanically fixed, so that the heat transfer and fixed connection between the first surface 11A of the heat spreading structure 11 and the chip to be heat dissipated can be realized. It should be noted that the ways of mechanical fixation can include but is not limited to fastener fixation, riveting fixation, etc.

In the embodiments of the present disclosure, the connection methods between the first surface 11A of the heat spreading structure 11 after being treated by the oxide skin removal process and the package of the chip to be heat dissipated may include, but is not limited to, the preceding welding method and the form of heat conducting medium plus mechanical fixation, and other connection methods may be selected according to an actual requirement.

In some possible embodiments, the first surface heat dissipation structure 12 is formed on the second surface that is treated by an oxide skin removal process.

In some possible embodiments, the second surface heat dissipation structure 13 is formed on the third surface that is treated by an oxide skin removal process.

In the following, a production process of the heat dissipation apparatus 10 will be explained to further describe the heat dissipation apparatus 10 in the embodiments of the present disclosure.

Exemplarily, FIG. 6 is a process flow diagram of the heat dissipation apparatus in an embodiment of the present disclosure. As shown in FIG. 6, in the process of producing the heat dissipation apparatus 10, the heat spreading structure 11 is first designed based on a size and a heat flux density of the chip to be heat dissipated, where only one heat spreading block 111 will be provided in the heat spreading structure 11, and the length and width of the heat spreading block 111 are set to be equal to the length and width of the chip to be heat dissipated, for example, the size of the heat spreading block 111 is 10 mm (L)×8 mm (W)×5 mm (H). After determining the size of the heat spreading block 111, a copper material with good thermal conductivity (red copper, density 8.96 g/cm³, thermal conductivity 400 W/m⋅K, specific heat capacity 390 J/kg⋅K) is used to machine the heat spreading block 111. The prepared heat spreading block 111 is shown in (a) of FIG. 6. Then, all surfaces of the heat spreading block 111 are subjected to an oxide skin removal treatment, and the heat spreading block 111 after the oxide skin removal treatment is as shown in (b) of FIG. 6. Then, except for the surface in contact with the chip to be heat dissipated, the remaining surfaces (i.e., the second surface 11B and the third surface 11C) of the heat spreading block 111 are processed by a copper powder spraying process, where a particle diameter of the copper powder is 50 μm, and the spraying pressure is 1 MPa. The heat spreading block 111 after copper powder spraying is as shown in (c) in FIG. 6. Then, a surface (i.e., the first surface 11A) of the heat spreading block 111 in contact with the top surface of the chip to be heat dissipated is subjected to a secondary removal treatment of oxide skin and welded together with the top surface of the chip to be heat dissipated.

In the embodiments of the present disclosure, by the copper powder spraying process, the first surface heat dissipation structure formed has a higher adhesion strength, and the shape of the first surface heat dissipation structure can be adjusted, thereby increasing the number of vaporization core and enhancing the boiling heat exchange effect of the heat dissipation apparatus.

It can be understood by the skilled in the art that the numerical order of the steps in the foregoing embodiments does not imply a sequential order of execution, and the order of execution of processes should be determined according to their function and internal logic, and should not constitute any limitation on the implementation of the embodiments of the present disclosure.

The foregoing embodiments are only used to describe the technical solutions of the present disclosure, but not to limit them; although the present disclosure has been described in detail with reference to the foregoing embodiments, persons of ordinary skill in the art should understand that they may still make modifications to the technical solutions described in the foregoing embodiments or make equivalent substitutions to some technical features therein; and these modifications and substitutions do not make the essence of corresponding technical solutions depart from the spirit and scope of the technical solutions of embodiments of the present disclosure, and should be included in the protection scope of the present disclosure.

What is claimed is:

1. A heat dissipation apparatus, comprising: a heat spreading structure and a first surface heat dissipation structure; wherein,
the heat spreading structure at least comprises a first surface and a second surface which are oppositely arranged, the first surface is connected with a package of a chip to be heat dissipated; and
the first surface heat dissipation structure is formed on the second surface by using a copper powder spraying process.

2. The apparatus according to claim 1, wherein, the heat spreading structure further comprises a third surface, and the heat dissipation apparatus further comprises a second surface heat dissipation structure, wherein the third surface is connected with the first surface and the second surface;
the second surface heat dissipation structure is formed on the third surface by using a copper powder spraying process.

3. The apparatus according to claim 1, wherein, a spraying thickness used in the copper powder spraying process is 0.05-0.15 mm.

4. The apparatus according to claim 2, wherein, a spraying thickness used in the copper powder spraying process is 0.05-0.15 mm.

5. The apparatus according to claim 1, wherein, a spraying pressure used in the copper powder spraying process is 0.2-1 MPa.

6. The apparatus according to claim 2, wherein, a spraying pressure used in the copper powder spraying process is 0.2-1 MPa.

7. The apparatus according to claim 1, wherein, the heat spreading structure further comprises at least one heat spreading block, and the at least one heat spreading block is provided above the package of the chip to be heat dissipated; and a bottom surface of the at least one heat spreading block constitutes the first surface, and a top surface of the at least one heat spreading block constitutes the second surface.

8. The apparatus according to claim 7, wherein, a shape of the heat spreading block is one of the following: cuboid, cube, frustum and cylinder.

9. The apparatus according to claim 1, wherein, the first surface is connected with the package of the chip to be heat dissipated.

10. The apparatus according to claim 9, wherein, the package of the chip to be heat dissipated is welded to the first surface.

11. The apparatus according to claim 9, wherein, a heat conducting medium layer is filled between the package of the chip to be heat dissipated and the first surface.

12. The apparatus according to claim 1, wherein, a surface of the first surface heat dissipation structure has a rough pattern.
